(19) United States
(12) Patent Application Publication
(10) Pub. No.: US 2023/0371284 A1
(43) Pub. Date: Nov. 16, 2023

(54) SEMICONDUCTOR DEVICE AND MANUFACTURING METHOD THEREOF

(71) Applicant: SK hynix Inc., Icheon-si Gyeonggi-do (KR)

(72) Inventor: Jae Taek KIM, Icheon-si Gyeonggi-do (KR)

(73) Assignee: SK hynix Inc., Icheon-si Gyeonggi-do (KR)

(21) Appl. No.: 17/896,193

(22) Filed: Aug. 26, 2022

(30) Foreign Application Priority Data
May 13, 2022 (KR) 10-2022-0059175

(51) Int. Cl. H01L 27/24; H01L 23/528; H01L 45/00

(52) U.S. Cl. CPC H01L 27/2481; H01L 23/5283; H01L 45/1675

(57) ABSTRACT

A semiconductor device includes a first gate structure including a first pad staircase structure and a first sidewall connected to the first pad staircase structure. The semiconductor device also includes a dummy stack including a dummy staircase structure and a first dummy sidewall connected to the dummy staircase structure, the first dummy sidewall including at least one first protrusion. The semiconductor device further includes a first insulating structure located between the first gate structure and the dummy stack.

### CROSS-REFERENCE TO RELATED APPLICATION

This application claims priority under 35 U.S.C. § 119(a) to Korean Patent Application No. 10-2022-0059175 filed on May 13, 2022, which is incorporated herein by reference in its entirety.

### BACKGROUND

### 1. Technical Field

Embodiments of the present disclosure relate to an electronic device, and more particularly, to a semiconductor device and a manufacturing method thereof.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a first gate structure including a first pad staircase structure and a first sidewall connected to the first pad staircase structure; a dummy stack including a dummy staircase structure and a first dummy sidewall connected to the dummy staircase structure, the first dummy sidewall including at least one first protrusion; and a first insulating structure located between the first gate structure and the dummy stack.

In an embodiment, a semiconductor device may include: a peripheral circuit; an interconnection structure electrically connected to the peripheral circuit; a first dummy stack located on the interconnection structure and including a dummy staircase structure; a second dummy stack located on the first dummy stack and including a dummy sidewall including at least one protrusion; an insulating structure formed on the first dummy stack and facing the dummy sidewall; and a contact plug penetrating at least the first dummy stack of the second dummy stack and the first dummy stack, the contact plug electrically connected to the interconnection structure.

In an embodiment, a manufacturing method of a semiconductor device may include: forming a stack including first material layers and second material layers which are alternately stacked; forming a first trench defining a first staircase structure within the stack; transferring the first staircase structure into the stack, thereby forming a second trench defining a second staircase structure and a sidewall connected to the second staircase structure and including at least one protrusion; and forming an insulating structure in the second trench.

In an embodiment, a manufacturing method of a semiconductor device may include: forming a first stack including a pad staircase structure and a sidewall connected to the pad staircase structure forming a dummy stack including a dummy staircase structure and a dummy sidewall connected to the dummy staircase structure, the dummy sidewall including protrusions; and forming an insulating structure between the first stack and the dummy stack.

### BRIEF DESCRIPTION OF THE DRAWINGS

FIG. 1A to FIG. 1D are diagrams for describing the structure of a semiconductor device in accordance with an embodiment.

FIG. 2A to FIG. 2C are diagrams for describing the structure of a semiconductor device in accordance with an embodiment.

FIG. 3A to FIG. 3C are diagrams illustrating the structure of a semiconductor device in accordance with an embodiment.

FIG. 4A to FIG. 4C are diagrams illustrating the structure of a semiconductor device in accordance with an embodiment.

FIG. 5A, FIG. 6A, FIG. 7A, and FIG. 8A and FIG. 5B, FIG. 6B, FIG. 7B, and FIG. 8B are diagrams for describing a manufacturing method of a semiconductor device in accordance with an embodiment.

### DETAILED DESCRIPTION

Various embodiments are directed to a semiconductor device having a stable structure and improved characteristics and a manufacturing method thereof.

In accordance with the present embodiment, it is possible to provide a semiconductor device having a stable structure and improved reliability.

Hereafter, embodiments in accordance with the present disclosure will be described with reference to the accompanying drawings.

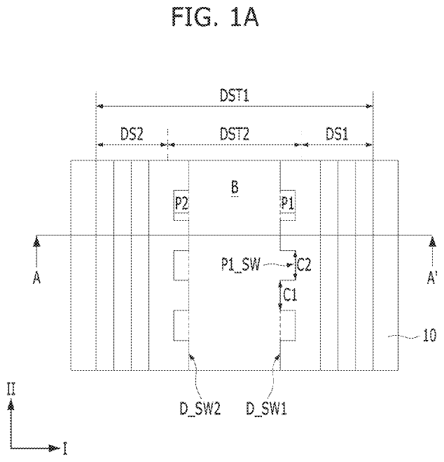

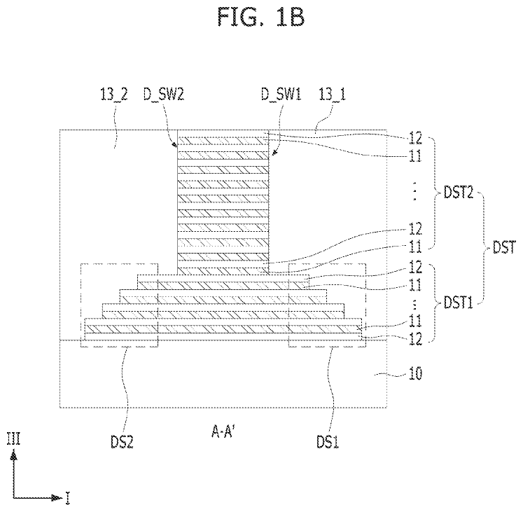

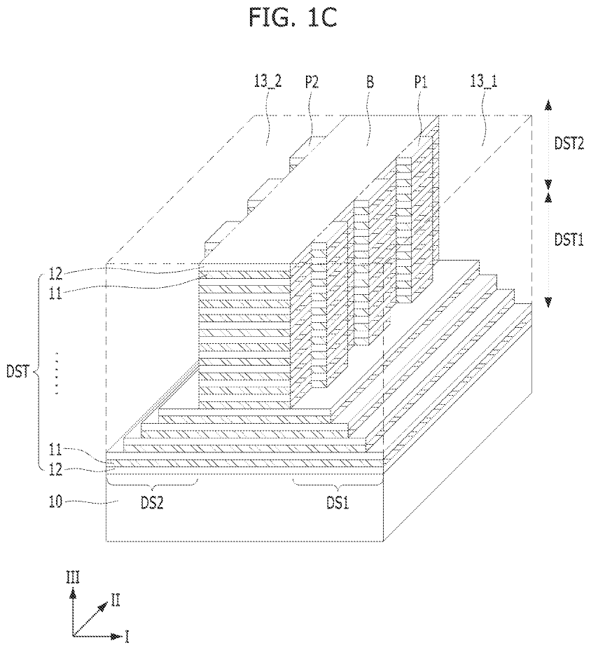

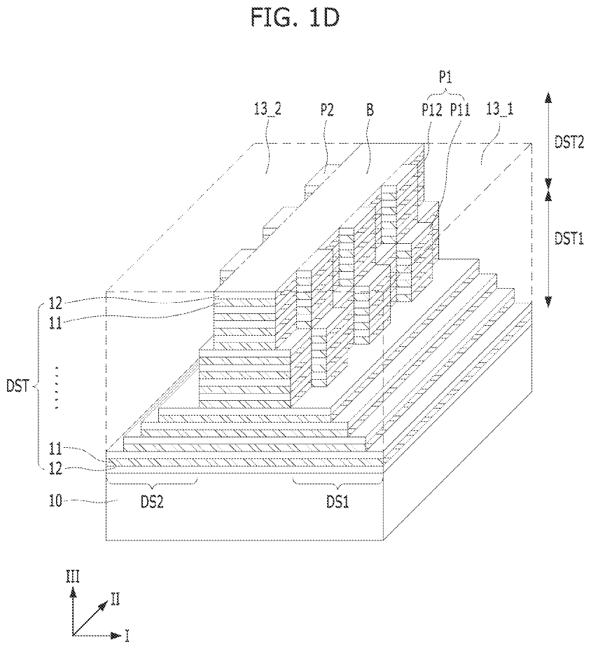

FIG. 1A to FIG. 1D are diagrams for describing the structure of a semiconductor device in accordance with an embodiment. FIG. 1A may be a plan view, FIG. 1B may be a cross-sectional view taken along line A-A′ of FIG. 1A, and FIG. 1C and FIG. 1D may be perspective views.

Referring to FIG. 1A to FIG. 1C, the semiconductor device may include a dummy stack DST. The dummy stack DST may be located on a base 10. The base 10 may include a lower structure (not illustrated) such as a substrate, a peripheral circuit, an interconnection structure, and a source structure.

The dummy stack DST may include first material layers 11 and second material layers 12 which are alternately stacked. For example, the first material layers 11 may each include a sacrificial material such as a nitride, and the second material layers 12 may each include an insulating material such as an oxide or a nitride. As another example, the first material layers 11 may each include a conductive material such as polysilicon, tungsten, or molybdenum, and the second material layers 12 may each include an insulating material such as an oxide or a nitride.

The dummy stack DST may include a first dummy stack DST1 and a second dummy stack DST2. The first dummy stack DST1 and the second dummy stack DST2 may be stacked in a third direction III. The second dummy stack DST2 may be located on the first dummy stack DST1. The third direction III may be a direction normal to a plane defined by a first direction I and an orthogonal second direction II.

The first dummy stack DST1 may include one or both of a first dummy staircase structure DS1 and a second dummy staircase structure DS2. The first dummy staircase structure DS1 or the second dummy staircase structure DS2 may include stairs whose heights change in the first direction I or the second direction II. Each stair may include at least one first material layer 11 and at least one second material layer 12. The first dummy staircase structure DS1 and the second dummy staircase structure DS2 may be located at levels corresponding to each other, and may be adjacent to each other in the first direction I. Corresponding levels, for example, means that corresponding features of different structures are located at substantially the same level.

The second dummy stack DST2 may include one or both of a first dummy sidewall D_SW1 and a second dummy sidewall D_SW2. The first dummy sidewall D_SW1 or the second dummy sidewall D_SW2 may extend in the second direction II. The first dummy sidewall D_SW1 may be connected to the first dummy staircase structure DS1, and the second dummy sidewall D_SW2 may be connected to the second dummy staircase structure DS2. The first dummy sidewall D_SW1 and the second dummy sidewall D_SW2 may be located at levels corresponding to each other, and may be adjacent to each other in the first direction I.

The second dummy stack DST2 may include a body B and at least one first protrusion P1. The body B may extend in the second direction II, and the first protrusions P1 may protrude from the body B in the first direction I. The first dummy sidewall D_SW1 may include at least one first protrusion P1. Referring to FIG. 1C, the first protrusions P1 may be located above the first dummy staircase structure DS1, and each of the first protrusions P1 may have a pillar shape.

The second dummy stack DST2 may further include at least one second protrusion P2. The second protrusions P2 may protrude from the body B in the first direction I. The second dummy sidewall D_SW2 may include at least one second protrusion P2. Referring to FIG. 1C, the second protrusions P2 may be located above the second dummy staircase structure DS2, and each of the second protrusions P2 may have a pillar shape.

The semiconductor device may further include a first insulating structure 13_1. The first insulating structure 13_1 may be located above the first dummy stack DST1, and may face the first dummy sidewall D_SW1. The first insulating structure 13_1 may fill between the first protrusions P1. Referring to FIG. 1C, the first insulating structure 13_1 may surround sidewalls of the first protrusions P1 each having a pillar shape. The first insulating structure 13_1 may include an insulating material such as an oxide or a nitride.

The semiconductor device may further include a second insulating structure 13_2. The second insulating structure 13_2 may be located above the first dummy stack DST1, and may face the second dummy sidewall D_SW2. The second insulating structure 13_2 may fill between the second protrusions P2. Referring to FIG. 1C, the second insulating structure 13_2 may surround sidewalls of the second protrusions P2 each having a pillar shape. The second insulating structure 13_2 may include an insulating material such as an oxide or a nitride.

The semiconductor device may include at least one first crack C1, or at least one second crack C2, or at least one first crack C1 and at least one second crack C2. The first crack C1 or the second crack C2 may be formed in the process of forming the first insulating structure 13_1 or the second insulating structure 13_2.

The first crack C1 may be located between the first dummy sidewall D_SW1 and the first insulating structure 13_1. The first crack C1 may extend in the second direction II along an interface between the first dummy sidewall D_SW1 and the first insulating structure 13_1, and may be isolated by the first protrusions P1. The first crack C1 may be located between the first protrusions P1 adjacent in the second direction II. For reference, the first crack C1 may also be located between the second dummy sidewall D_SW2 and the second insulating structure 13_2.

The second crack C2 may be located between the first protrusion P1 and the first insulating structure 13_1. The second crack C2 may extend in the second direction II along an interface between the first protrusion P1 and the first insulating structure 13_1. The second crack C2 may be located to correspond to the sidewall of the first protrusion P1 and may be separated from the first crack C1.

Referring to FIG. 1D, the first protrusion P1 may include a first sub-protrusion P11 and a second sub-protrusion P12. The first sub-protrusion P11 and the second sub-protrusion P12 may be located at different levels in the third direction III. The first sub-protrusion P11 and the second sub-protrusion P12 may be aligned or offset in the first direction I or the second direction II. The second protrusion P2 may also include sub-protrusions like the first protrusion P1.

According to the structure described above, the dummy stack DST includes the first protrusions P1 or the second protrusions P2. When the dummy stack DST does not include the first protrusions P1, the first crack C1 may extend long in the second direction II along the interface between the first dummy sidewall D_SW1 and the first insulating structure 13_1. Accordingly, the first protrusion P1 is included in the first dummy sidewall D_SW1, which makes it possible to minimize or prevent the extension of the first crack C1. The length of the first crack C1 may be limited by the first protrusions P1.

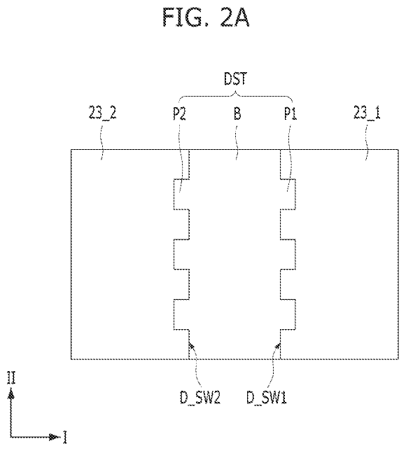

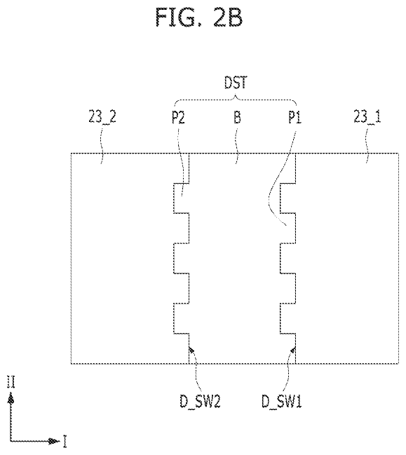

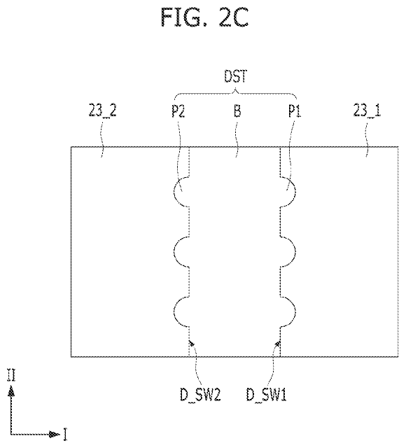

FIG. 2A to FIG. 2C are diagrams for describing the structure of a semiconductor device in accordance with an embodiment, and may be plan views illustrating various shapes of protrusions. In the following descriptions, the overlapping contents of the above-described description will be omitted.

Referring to FIG. 2A to FIG. 2C, the semiconductor device may include the dummy stack DST, a first insulating structure 23_1, or a second insulating structure 23_2, or include a combination thereof. The dummy stack DST may include the first dummy sidewall D_SW1, and the first dummy sidewall D_SW1 may include the first protrusions P1. The first protrusions P1 may protrude into the first insulating structure 23_1. The dummy stack DST may include the second dummy sidewall D_SW2, and the second dummy sidewall D_SW2 may include the second protrusions P2. The second protrusions P2 may protrude into the second insulating structure 23_2. The first protrusions P1 and/or the second protrusions P2 may be arranged adjacent to one another in the second direction II, and may be spaced apart from each other at uniform or non-uniform intervals.

In the plane defined in the first direction I and the second direction II, the first protrusions P1 and/or the second protrusions P2 may each have a shape of a rectangle, a polygon, a circle, or an oval, or may each have a shape including a part of a rectangle, a polygon, a circle, and an oval. Referring to FIG. 2A and FIG. 2B, the first protrusions P1 and/or the second protrusions P2 may each have a rectangular shape. Referring to FIG. 2C, the first protrusions P1 and/or the second protrusions P2 may each have a shape including a curve. In addition, the first protrusions P1 and/or the second protrusions P2 may each have a shape in which a curved line and a straight line are combined.

The first protrusions P1 and the second protrusions P2 may be adjacent to each other in the first direction I. The number of the first protrusions P1 and the number of the second protrusions P2 included in the dummy stack DST may be the same as or different from each other. The first protrusions P1 and the second protrusions P2 may have the same shape or size or may have different shapes or sizes. The first protrusions P1 and the second protrusions P2 may be arranged in a symmetrical manner or an asymmetrical manner about the body B. Referring to FIG. 2A and FIG. 2C, the first protrusions P1 and the second protrusions P2 may be arranged in a symmetrical shape. Referring to FIG. 2B, the first protrusions P1 and the second protrusions P2 may be arranged in an asymmetrical manner.

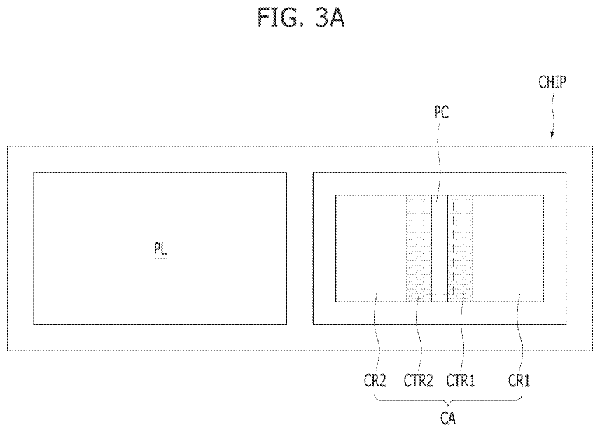

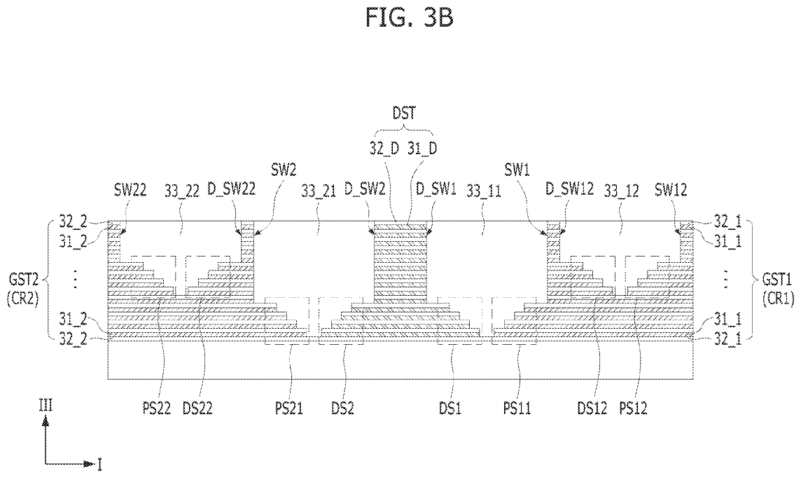

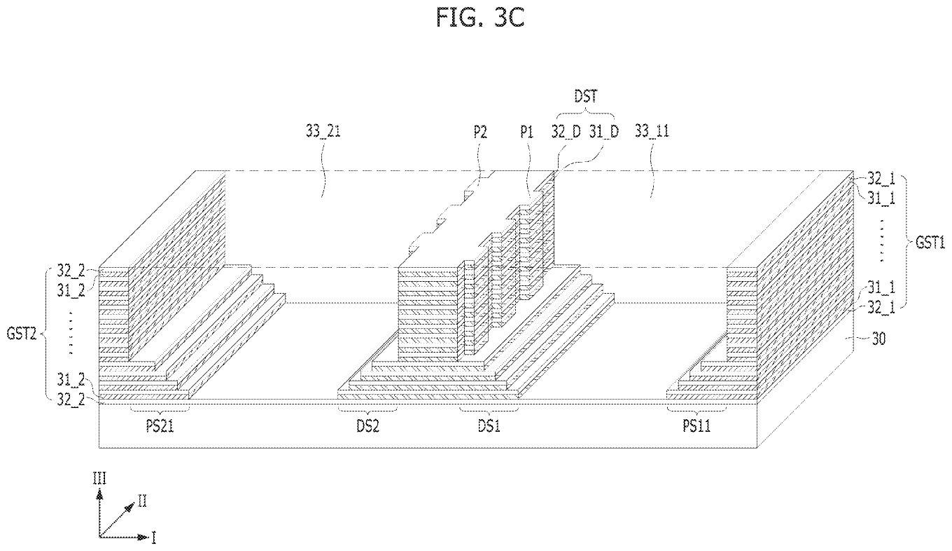

FIG. 3A to FIG. 3C are diagrams illustrating a structure of a semiconductor device in accordance with an embodiment. FIG. 3A may be a plan view, FIG. 3B may be a cross-sectional view, and FIG. 3C may be a perspective view. In the following descriptions, the overlapping contents of the above-described description will be omitted.

Referring to FIG. 3A, the semiconductor device may include a chip CHIP, and the chip CHIP may include a plurality of planes PL. The planes PL may be arranged in one direction or in a matrix form. Each of the planes PL may include a plurality of memory blocks, and each memory block may include a cell array area CA and a peripheral circuit area PC.

The cell array area CA may be an area in which a cell array is located. The cell array area CA may include a first cell region CR1, a second cell region CR2, a first contact region CTR1, or a second contact region CTR2, or include a combination thereof. The first contact region CTR1 and the second contact region CTR2 may be located between the first cell region CR1 and the second cell region CR2. A first gate structure may be located in the first cell region CR1 and the first contact region CTR1. The first gate structure may include first memory cells located in the first cell region CR1, and may include a first pad staircase structure located in the first contact region CTR1. The second gate structure may include second memory cells located in the second cell region CR2, and may include a second pad staircase structure located in the second contact region CTR2. A dummy stack may be located between the first gate structure and the second gate structure.

The peripheral circuit area PC may be an area in which a circuit for driving the cell array is located. The peripheral circuit area PC may be located between the first cell region CR1 and the second cell region CR2. The peripheral circuit area PC may be located below the first contact region CTR1, below the second contact region CTR2, or below the first contact region CTR1 and the second contact region CTR2.

Referring to FIG. 3B and 3C, the semiconductor device may include the dummy stack DST, a first gate structure GST1, and first insulating structures 33_11 and 33_12. The semiconductor device may further include a base 30, a second gate structure GST2, or second insulating structures 33_21 and 33_22, or may further include a combination thereof.

The base 30 may include a lower structure (not illustrated) such as a substrate, a peripheral circuit, an interconnection structure, and a source structure. The first gate structure GST1, the dummy stack DST, or the second gate structure GST2 may be located on the base 30. The first gate structure GST1 and the second gate structure GST2 may be adjacent to each other in the first direction I. The dummy stack DST may be located between the first gate structure GST1 and the second gate structure GST2. The first insulating structure 33_11 may be located between the first gate structure GST1 and the dummy stack DST. The second insulating structure 33_21 may be located between the second gate structure GST2 and the dummy stack DST.

The dummy stack DST may include first material layers 31_D and second material layers 32_D which are alternately stacked. The first gate structure GST1 may include first conductive layers 31_1 and first insulating layers 32_1 which are alternately stacked. The second gate structure GST2 may include second conductive layers 31_2 and second insulating layers 32_2 which are alternately stacked. The first conductive layers 31_1 or the second conductive layers 31_2 may each include a conductive material such as polysilicon, tungsten, or molybdenum. The first insulating layers 32_1 or the second insulating layers 32_2 may each include an insulating material such as an oxide, a nitride, or an air gap.

The first material layers 31_D, the first conductive layers 31_1, and the second conductive layers 31_2 may be located at levels corresponding to one another. The second material layers 32_D, the first insulating layers 32_1, and the second insulating layers 32_2 may be located at levels corresponding to one another. The first material layers 31_D may be sacrificial materials remaining without being replaced with the first conductive layers 31_1 or the second conductive layers 31_2 during a manufacturing process.

The dummy stack DST may include the first dummy staircase structure DS1 and the first dummy sidewall D_SW1 connected to the first dummy staircase structure DS1. The first dummy sidewall D_SW1 may extend in the second direction II. The first dummy sidewall D_SW1 may include the first protrusions P1. The first protrusions P1 may protrude toward the first gate structure GST1. The first protrusions P1 may protrude into the first insulating structure 33_11.

The first gate structure GST1 may include a first sidewall SW1 connected to a first pad staircase structure PS11. The first sidewall SW1 may extend in the second direction II. The first pad staircase structure PS11 may be located to face the first dummy staircase structure DS1, and may be located at levels corresponding to each other. The first sidewall SW1 and the first dummy sidewall D_SW1 may be located to face each other, and may be located at levels corresponding to each other.

The first gate structure GST1 may further include a first pad staircase structure PS12, a first sidewall SW12, a dummy staircase structure DS12, or a dummy sidewall D_SW12, or may further include a combination thereof. The first pad staircase structure PS12 may be located at a different level from that of the first pad staircase structure PS11. The first sidewall SW12 may be connected to the first pad staircase structure PS12. The dummy staircase structure DS12 may be located to face the first pad staircase structure PS12. The dummy sidewall D_SW12 may be connected to the dummy staircase structure DS12. The first insulating structure 33_12 may be located on the first pad staircase structure PS12 and the dummy staircase structure DS12, and may face the first sidewall SW12 or the dummy sidewall D_SW12.

The dummy stack DST may further include the second dummy staircase structure DS2 and the second dummy sidewall D_SW2 connected to the second dummy staircase structure DS2. The second dummy sidewall D_SW2 may extend in the second direction II. The second dummy sidewall D_SW2 may include the second protrusions P2. The second protrusions P2 may protrude toward the second gate structure GST2. The second protrusions P2 may protrude into the second insulating structure 33_21. The second protrusions P2 and the first protrusions P1 may be located at levels corresponding to each other.

The second gate structure GST2 may further include a second pad staircase structure PS22, a second sidewall SW22, a dummy staircase structure DS22, or a dummy sidewall D_SW22, or may further include a combination thereof. The second pad staircase structure PS22 may be located at a different level from that of the second pad staircase structure PS21. The second sidewall SW22 may be connected to the second pad staircase structure PS22. The dummy staircase structure DS22 may be located to face the second pad staircase structure PS22. The dummy sidewall D_SW22 may be connected to the dummy staircase structure DS22. The second insulating structure 33_22 may be located on the second pad staircase structure PS22 and the dummy staircase structure DS22, and face the second sidewall SW22 or the dummy sidewall D_SW22.

For reference, although not illustrated in the drawings, the first sidewalls SW1 and SW12, the second sidewalls SW2 and SW22, or the dummy sidewalls D_SW12 and D_SW22 may each include protrusions. In an embodiment, the first sidewall SW1 may include at least one protrusion protruding into the first insulating structure 33_11. The dummy sidewall D_SW12 may include at least one protrusion protruding into the first insulating structure 33_12. The first sidewall SW12 may include at least one protrusion protruding into the first insulating structure 33_12.

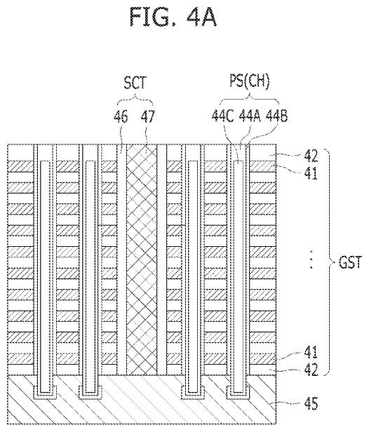

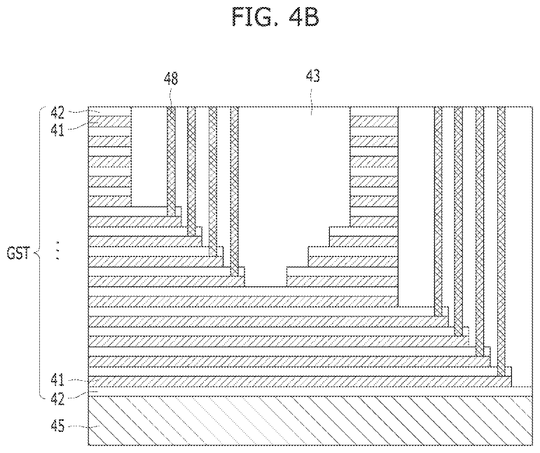

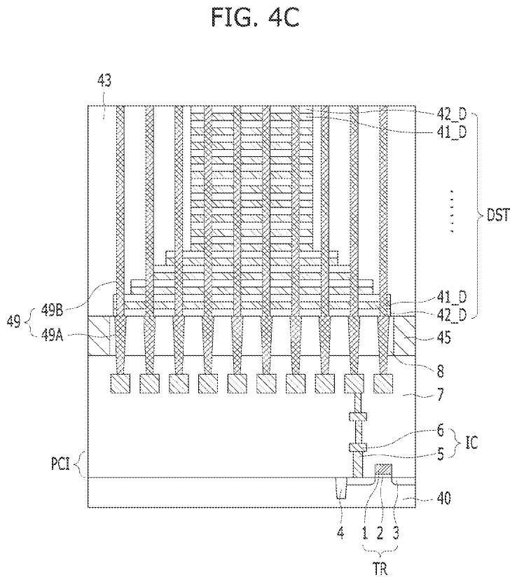

FIG. 4A to FIG. 4C are diagrams illustrating the structure of a semiconductor device in accordance with an embodiment. In the following descriptions, the overlapping contents of the above-described description will be omitted.

Referring to FIG. 4A, the semiconductor device may include a gate structure GST, a penetration structure PS, a source structure 45, or a source contact structure SCT, or a combination thereof.

The gate structure GST may be located on the source structure 45. The source structure 45 may be a part of the base described above. The source structure 45 may be a separate conductive layer formed on the substrate or may be an impurity region in the substrate. The gate structure GST may include conductive layers 41 and insulating layers 42 which are alternately stacked. The conductive layers 41 may each be a word line, a bit line, or a selection line. In an embodiment, among the conductive layers 41, at least one lowermost conductive layer may be a source selection line, at least one uppermost conductive layer may be a drain selection line, and the remaining conductive layers may be word lines.

The penetration structure PS may penetrate the gate structure GST and extend to the source structure 45. Memory cells may be located at intersection regions of the penetration structure PS and the conductive layers 41. The memory cells may be stacked along the penetration structure PS.

In an embodiment, the penetration structure PS may be a channel structure CH. The channel structure CH may include a channel layer 44A penetrating the gate structure GST. The channel structure CH may further include a memory layer 44B surrounding an outer wall of the channel layer 44A or an insulating core 44C within the channel layer 44A. The memory layer 44B may include a tunneling layer, a data storage layer, or a blocking layer, or include a combination thereof. The channel structure CH may be connected to the source structure 45. In an embodiment, the channel layer 44A may be directly connected to the source structure 45 or may be connected to the source structure 45 through a semiconductor pattern grown by an epitaxial method.

In an embodiment, the penetration structure PS may be an electrode structure. The electrode structure may include an electrode layer penetrating the gate structure GST, and may further include a memory layer surrounding an outer wall or inner wall of the electrode layer. The memory layer may include a variable resistance material.

The source contact structure SCT may penetrate the gate structure GST and extend to the source structure 45. The source contact structure SCT may include a contact plug 47 electrically connected to the source structure 45 and an insulating spacer 46 surrounding a sidewall of the contact plug 47. The contact plug 47 may include a conductive material such as polysilicon, tungsten, molybdenum, or a metal.

Referring to FIG. 4B, the semiconductor device may include the gate structure GST, an insulating structure 43, or contact plugs 48, or include a combination thereof. The gate structure GST may include the conductive layers 41 and the insulating layers 42 which are alternately stacked. The gate structure GST may include a pad staircase structure, and the conductive layers 41 or the insulating layers 42 may be exposed through the pad staircase structure. An exposed portion of each of the conductive layers 41 may be used as a pad. The insulating structure 43 may be located on the staircase structure. The contact plugs 48 may be electrically connected to the respective pads of the conductive layers 41 by penetrating the insulating structure 43.

Referring to FIG. 4C, the semiconductor device may include the dummy stack DST, the insulating structure 43, contact plugs 49, a source structure 45, an interlayer insulating layer 7, a substrate 40, or a peripheral circuit PCI, or may include a combination thereof.

The dummy stack DST may be located on the source structure 45. The source structure 45 may be a part of the base described above. The source structure 45 may be a separate conductive layer formed on the substrate. The source structure 45 may include an insulating pattern 8.

The dummy stack DST may include first material layers 41_D and second material layers 42_D which are alternately stacked. The dummy stack DST may include a dummy staircase structure, and the first material layers 41_D or the second material layers 42_D may be exposed through the dummy staircase structure. An insulating structure 43 may be located on the dummy staircase structure.

An isolation layer 4 may be located in the substrate 40, and an active region may be defined by the isolation layer 4. The peripheral circuit PCI may be located on the substrate 40. The peripheral circuit PCI may include a transistor TR. The transistor TR may include a gate electrode 1, a gate insulating layer 2, or a junction 3, or include a combination thereof. The gate insulating layer 2 may be located between the gate electrode 1 and the substrate 40, and the junction 3 may be an impurity region formed in the substrate 40.

The interlayer insulating layer 7 may be located between the substrate 40 and the source structure 45. An interconnection structure IC may be located in the interlayer insulating layer 7. The interconnection structure IC may include at least one contact plug 5 and/or at least one wiring line 6. The interconnection structure IC may be located below the dummy stack DST and may be electrically connected to the peripheral circuit PCI.

The contact plugs 49 may penetrate the dummy stack DST. At least one of the contact plugs 49 may penetrate the protrusion of the dummy stack DST. The contact plugs 49 may further penetrate the insulating structure 43, the insulating pattern 8, and/or the interlayer insulating layer 7. Each of the contact plugs 49 may include a first contact plug 49A penetrating the insulating pattern 8 and a second contact plug 49B penetrating the dummy stack DST. The contact plugs 49 may be electrically connected to the peripheral circuit PCI through the interconnection structure IC.

For reference, although not illustrated in the drawings, an insulating spacer may also be formed on sidewalls of the contact plugs 49. In an embodiment, when the first material layers 41_D each include a conductive material, the contact plugs 49 and the first material layers 41_D may be insulated from each other by the insulating spacer.

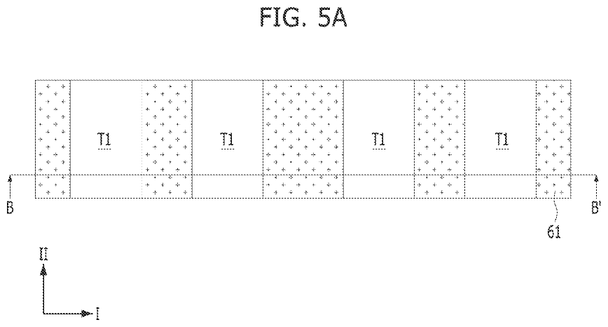

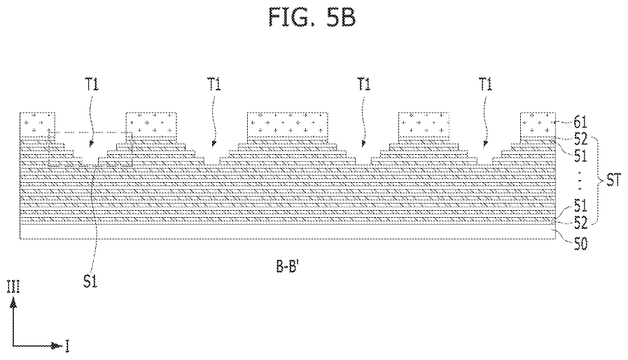

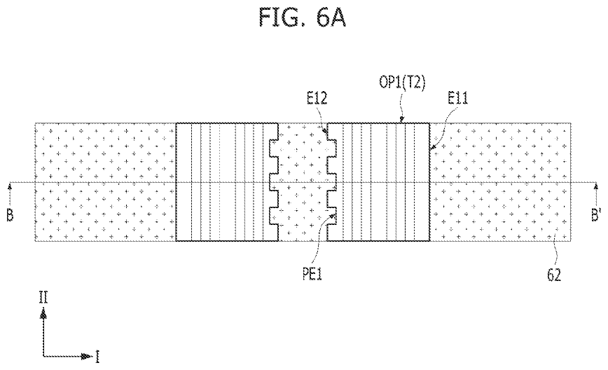

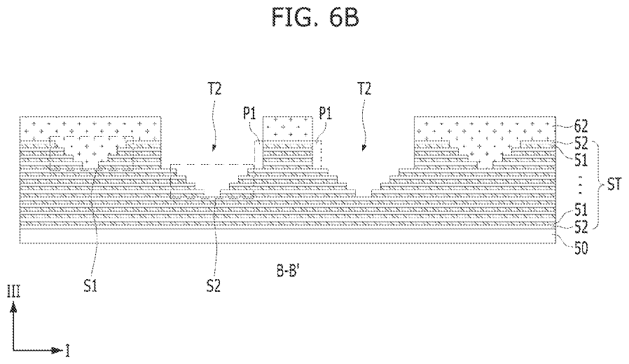

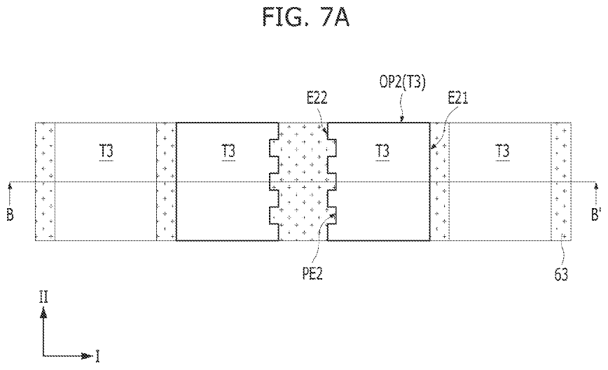

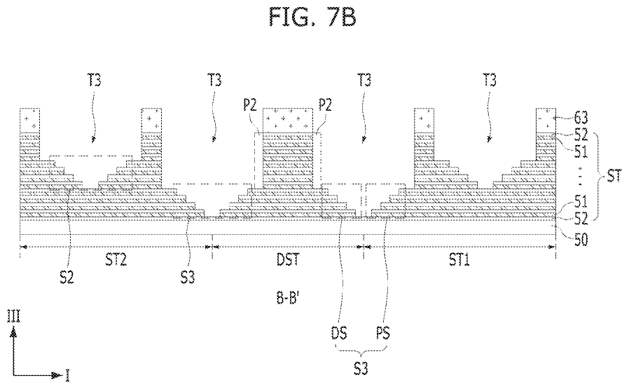

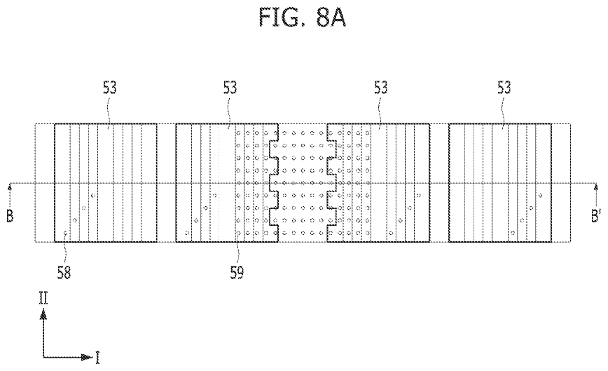

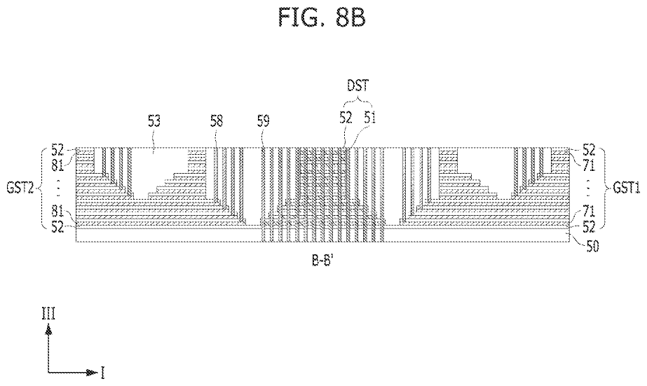

FIG. 5A, FIG. 6A, FIG. 7A, and FIG. 8A and FIG. 5B, FIG. 6B, FIG. 7B, and FIG. 8B are diagrams illustrating a manufacturing method of a semiconductor device in accordance with an embodiment. FIG. 5B, FIG. 6B, FIG. 7B, and FIG. 8B may be sectional views taken along lines B-B′ of FIG. 5A, FIG. 6A, FIG. 7A, and FIG. 8A, respectively.

Referring to FIG. 5A and FIG. 5B, a stack ST may be formed on a base 50. The stack ST may include first material layers 51 and second material layers 52 which are alternately stacked. The first material layers 51 may be used to form a word line, a bit line, and a selection line, and the second material layers 52 may be used to form an insulating layer. The first material layers 51 may each include a material having a high etch selectivity with respect to the second material layers 52. For example, the first material layers 51 may each include a sacrificial material such as a nitride, and the second material layers 52 may each include an insulating material such as an oxide. As another example, the first material layers 51 may each include a conductive material such as polysilicon, tungsten, or molybdenum, and the second material layers 52 may each include an insulating material such as an oxide.

Subsequently, first trenches T1 may be formed in the stack ST. The first trenches T1 may be adjacent in the first direction I. Each of the first trenches T1 may define a first staircase structure S1 in the stack ST. The first staircase structure S1 may have a staircase shape whose height changes along the first direction. The first staircase structure S1 may have both sides each including a staircase structure, and the staircase structures on both the sides may have a symmetrical shape or an asymmetrical shape.

In an embodiment, a first mask pattern 61 is formed on the stack ST, and then the stack ST is etched using the first mask pattern 61 as an etching barrier. Subsequently, the first mask pattern 61 is reduced, and then the stack ST is etched. In this way, by repeating the process of reducing the first mask pattern 61 and etching the stack ST, the first staircase structure S1 may be formed. Subsequently, the first mask pattern 61 may be removed.

Referring to FIG. 6A and FIG. 6B, second trenches T2 may be formed in the stack ST. The second trenches T2 may be formed by extending at least one of the first trenches T1 into the stack ST. Second staircase structures S2 may be defined by the second trenches T2. The second staircase structure S2 may be a transfer of the first staircase structure S1.

In an embodiment, a second mask pattern 62 is formed on the stack ST. The second mask pattern 62 may include at least one first opening OP1 that exposes at least one of the first trenches T1. The first staircase structure S1 may be exposed through the first opening OP1. The first opening OP1 may include a first edge E11 and a second edge E12 facing the first edge E11. The first edge E11 or the second edge E12 may include at least one first protruding edge PE1. Subsequently, the stack ST may be etched using the second mask pattern 62 as an etching barrier to form the second trenches T2. The first staircase structure S1 may be transferred downward by a depth, at which the stack ST is etched, to form the second staircase structure S2. The first protrusions P1 may be formed at positions corresponding to the first protruding edges PE1. Subsequently, the second mask pattern 62 may be removed.

Referring to FIG. 7A and FIG. 7B, third trenches T3 may be formed in the stack ST. The third trenches T3 may be formed by extending at least one of the first trenches T1 and the second trenches T2 into the stack ST. The second staircase structure S2 or a third staircase structure S3 may be defined by the third trenches T3. The second staircase structure S2 may be a transfer of the first staircase structure S1, and the third staircase structure S3 may be a transfer of the second staircase structure S2.

In an embodiment, a third mask pattern 63 is formed on the stack ST. The third mask pattern 63 may include at least one second opening OP2 that exposes at least one of the first staircase structures S1 or the second staircase structures S2. The second opening OP2 may include a first edge E21 and a second edge E22 facing the first edge E21. The first edge E21 or the second edge E22 may include at least one second protruding edge PE2. The second protruding edge PE2 may be located to correspond to or to be offset from the first protruding edge PE1.

Subsequently, the stack ST may be etched using the third mask pattern 63 as an etching barrier to form the third trenches T3. The first staircase structure S1 or the second staircase structure S2 may be transferred downward by a depth at which the stack ST is etched. The first staircase structure S1 may be transferred downward by the second opening OP2 exposing the first staircase structure S1 to form the second staircase structure S2. The second staircase structure S2 may be transferred downward by the second opening OP2 exposing the second staircase structure S2 to form the third staircase structure S3. The third staircase structure S3 may include a pad staircase structure PS and a dummy staircase structure DS facing each other. The second protrusions P2 may be formed at positions corresponding to the second protruding edges PE2. The second protrusions P2 may be formed by extending the first protrusions P1 downward. Alternatively, the second protrusions P2 may be located to be offset from the first protrusions P1.

The stack ST may be separated into the dummy stack DST, a first stack ST1, and a second stack ST2 by the third trench T3. The dummy stack DST may include the dummy staircase structure DS and the dummy sidewall D_SW connected to the dummy staircase structure DS and including the second protrusions P2. The first stack ST1 may include a plurality of pad staircase structures PS located at different levels. The second stack ST2 may include a plurality of pad staircase structures PS located at different levels. Subsequently, the third mask pattern 63 may be removed.

Referring to FIG. 8A and FIG. 8B, insulating structures 53 may be formed in the third trenches T3. In an embodiment, an insulating layer may be formed by depositing an insulating material in the third trench T3 using a deposition process, and then the insulating structures 53 may be formed by planarizing the insulating layer until the upper surface of the first stack ST1, the second stack ST2, or the dummy stack DST is exposed. The third trench T3 may have a large aspect ratio, and a crack may occur in the process of filling the inside of the third trench T3 with the insulating material. A crack may be formed at an interface between the inner wall of the third trench T3 and the insulating structure 53, but it is possible to minimize or prevent the extension of the crack in the second direction II by the second protrusions P2.

Subsequently, the first material layers 51 may be replaced with third material layers. The third material layers may each include a metal such as tungsten or molybdenum. In an embodiment, the first material layers 51 of the first stack ST1 may be replaced with first conductive layers 71, and the first material layers 51 of the second stack ST2 may be replaced with second conductive layers 81, respectively. Through this, the first gate structure GST1 and the second gate structure GST2 may be formed. The first material layers 51 of the dummy stack DST may remain without being replaced.

Subsequently, first contact plugs 59 or second contact plugs 58 may be formed. The first contact plugs 59 and the second contact plugs 58 may be simultaneously formed or formed through separate processes.

The first contact plugs 59 may penetrate the dummy stack DST. The first contact plugs 59 may penetrate the second protrusions P2 of the dummy stack DST. The first contact plugs 59 may further penetrate the insulating structure 53. The second contact plugs 58 may penetrate the insulating structure 53, and may be connected to the first conductive layers 71 or the second conductive layers 81, respectively.

According to the manufacturing method as described above, in the process of transferring a staircase structure downward, a protrusion protruding into a trench may be formed. Consequently, even though a crack occurs in the process of forming an insulating structure in the trench, it is possible to minimize or prevent the extension of the crack in the second direction II.

Although embodiments according to the technical idea of the present disclosure have been described above with reference to the accompanying drawings, this is only for describing embodiments according to the concept of the present disclosure, and the present disclosure is not limited to the above embodiments. Various types of substitutions, modifications, and changes for the embodiments may be made by those skilled in the art, to which the present disclosure pertains without departing from the technical idea of the present disclosure defined in the following claims, and it should be construed that these substitutions, modifications, and changes belong to the scope of the present disclosure.

What is claimed is:

1. A semiconductor device comprising:
a first gate structure including a first pad staircase structure and a first sidewall connected to the first pad staircase structure;
a dummy stack including a dummy staircase structure and a first dummy sidewall connected to the dummy staircase structure, the first dummy sidewall including at least one first protrusion; and
a first insulating structure located between the first gate structure and the dummy stack.

2. The semiconductor device of claim 1, wherein the at least one first protrusion protrudes into the first insulating structure.

3. The semiconductor device of claim 1, wherein the first pad staircase structure and the dummy staircase structure are positioned at corresponding levels, and the first sidewall and the first dummy sidewall are positioned at corresponding levels.

4. The semiconductor device of claim 1, wherein:
the first gate structure and the dummy stack are adjacent to each other in a first direction, and
the first sidewall and the first dummy sidewall extend in a second direction intersecting the first direction.

5. The semiconductor device of claim 1, further comprising:
a crack located between the first dummy sidewall and the first insulating structure.

6. The semiconductor device of claim 5, wherein the crack is isolated by the first protrusions.

7. The semiconductor device of claim 1, further comprising:
at least one contact plug penetrating the at least one first protrusion.

8. The semiconductor device of claim 7, further comprising:
an interconnection structure located below the dummy stack and electrically connected to the contact plug.

9. The semiconductor device of claim 1, further comprising:
a second gate structure including a second pad staircase structure and a second sidewall connected to the second pad staircase structure; and
a second insulating structure located between the second gate structure and the dummy stack.

10. The semiconductor device of claim 9, wherein the dummy stack includes a second dummy sidewall, and the second dummy sidewall includes at least one second protrusion protruding into the second insulating structure.

11. The semiconductor device of claim 10, wherein the at least one first protrusion and the at least one second protrusion are located at corresponding levels.

12. The semiconductor device of claim 10, wherein the at least one first protrusion and the at least one second protrusion are arranged in a symmetrical manner or an asymmetrical manner.

13. A semiconductor device comprising:
a peripheral circuit;
an interconnection structure electrically connected to the peripheral circuit;
a first dummy stack located on the interconnection structure and including a dummy staircase structure;
a second dummy stack located on the first dummy stack and including a dummy sidewall including at least one protrusion;
an insulating structure formed on the first dummy stack and facing the dummy sidewall; and
a contact plug penetrating at least the first dummy stack of the second dummy stack and the first dummy stack, the contact plug electrically connected to the interconnection structure.

14. The semiconductor device of claim 13, wherein the at least one protrusion protrudes into the insulating structure.

15. The semiconductor device of claim 13, further comprising:
a crack located between the dummy sidewall and the insulating structure.

16. The semiconductor device of claim 15, wherein the crack is isolated by the at least one protrusion.

17. A manufacturing method of a semiconductor device, the manufacturing method comprising:
forming a stack including first material layers and second material layers which are alternately stacked;
forming a first trench defining a first staircase structure within the stack;
transferring the first staircase structure into the stack, thereby forming a second trench defining a second staircase structure and a sidewall connected to the second staircase structure and including at least one protrusion; and
forming an insulating structure in the second trench.

18. The manufacturing method of claim 17, wherein, in forming the second trench, the second staircase structure including a pad staircase structure and a dummy staircase structure facing each other is formed by etching the stack, and a dummy sidewall connected to the dummy staircase structure includes the at least one protrusion.

19. The manufacturing method of claim 18, wherein, in forming the second trench, the stack is separated by the second trench into a first stack including the pad staircase structure and a dummy stack including the dummy staircase structure and the dummy sidewall.

20. The manufacturing method of claim 17, wherein forming the second trench comprises:
forming a mask pattern including an opening that exposes the first staircase structure, the opening including at least one protruding edge; and
etching the stack by using the mask pattern as an etching barrier.

21. The manufacturing method of claim 20, wherein:
the second staircase structure includes a pad staircase structure and a dummy staircase structure facing each other,
the opening includes a first edge adjacent to the pad staircase structure and a second edge adjacent to the dummy staircase structure, and
the second edge includes the protruding edge.

22. The manufacturing method of claim 17, further comprising, before forming the stack:
forming an interconnection structure; and
forming a contact plug penetrating the protrusion and electrically connecting to the interconnection structure.

23. The manufacturing method of claim 17, wherein, in forming the insulating structure, between the protrusions, a crack occurs at an interface between the sidewall and the insulating structure.

24. The manufacturing method of claim 17, further comprising:
forming an interconnection structure; and
forming a contact plug penetrating the stack and electrically connected to the interconnection structure.

25. A manufacturing method of a semiconductor device, the manufacturing method comprising:
forming a first stack including a pad staircase structure and a sidewall connected to the pad staircase structure;
forming a dummy stack including a dummy staircase structure and a dummy sidewall connected to the dummy staircase structure, the dummy sidewall including protrusions; and
forming an insulating structure between the first stack and the dummy stack.

26. The manufacturing method of claim 25, further comprising:
forming a stack including first material layers and second material layers which are alternately stacked; and
forming a first trench defining a first staircase structure within the stack.

27. The manufacturing method of claim 26, wherein a second trench is formed by transferring the first staircase structure into the stack, thereby separating the stack into the first stack and the dummy stack, the second trench defining a second staircase structure.

28. The manufacturing method of claim 27, wherein the second staircase structure includes the pad staircase structure and the dummy staircase structure facing each other.

29. The manufacturing method of claim 25, wherein, in forming the insulating structure, between the protrusions, a crack occurs at an interface between the dummy sidewall and the insulating structure.

30. The manufacturing method of claim 25, further comprising:
forming a contact plug penetrating the dummy stack.
